(19) United States
(12) Patent Application Publication
(10) Pub. No.: US 2003/0024698 A1
(43) Pub. Date: Feb. 6, 2003

(54) Flexible coupling for heat sink

(75) Inventor: Henry C. Bosak III, Hillsboro, OR (US)

Correspondence Address: IBM CORPORATION, IP LAW DEPT, ED02-905, 15450 SW KOLL PARKWAY, BEAVERTON, OR, 97006-6063, US

(73) Assignee: International Business Machines Corporation, Armonk, NY

(21) Appl. No.: 09/920,700

(22) Filed: Aug. 1, 2001

(51) Int. Cl. F28F 7/00; H05K 7/20

(52) U.S. Cl. 165/185; 361/708; 165/80.3

(57) ABSTRACT

A flexible coupling for bonding a heat source to a heat dissipator. The coupling is comprised of a diaphragm and an interface. Both the diaphragm and the interface are comprised of thermally conductive materials. The interface bonds with the heat source, and the perimeter of the diaphragm is mounted to a wall of a vapor chamber. The resilient characteristic of the diaphragm enables bonding with a single heat source or multiple heat sources. In addition, the diaphragm provides a uniform bond-line surface between the heat source and the heat dissipator. Accordingly, the flexible coupling reduces thermal resistance associated with bonding coplanar and misaligned surfaces by mitigating non-uniform application of thermal interface materials.

### BACKGROUND OF THE INVENTION

1. Technical Field

This invention relates to an apparatus for bonding a heat source to a heat sink or other heat dissipating device.

2. Description of the Prior Art

In general, thermal interface materials are used to couple a heat source to a heat dissipation device. The area of the heat source and the heat dissipation device that bond are generally coplanar surfaces. Thermal interface materials are utilized to fill gaps that may form between the two coplanar surfaces. Gaps may occur between the two coplanar surfaces for a variety of reasons, including micro surface roughness between two surfaces, and non-alignment of the coplanar surfaces. In addition, thermal interface materials may be utilized for bonding misaligned surfaces. The thermal interface materials increase the thermal conductivity between the bonded surfaces as well as reduce the thermal resistance. Accordingly, it is desirable to utilize a thermal interface material of minimal bond-line between the heat source and the heat sink in order to both increase thermal conductivity and to reduce thermal resistance.

Solutions for minimizing the gap have become more critical as flux densities increase. Several solutions have been developed to mitigate gaps formed between the coplanar surfaces. Such solutions include: thermal greases, phase change materials, compliant foams, and epoxies. The following is an example of the temperature rise associated with thermal resistance between a heat dissipating device and a heat source: A 100 Watt device that has an area of 0.625 square millimeters, and a gap filler material of 0.0254 mm thick with a thermal conductivity of 1 W/m-K, would yield a thermal resistance of 0.4064 degrees Celsius per Watt. For 100 watts there would be a 4.064 degrees Celsius rise across the space. If the interface material was increased to a thickness of 0.127 mm a temperature increase of 20.32 degrees Celsius across the gap would occur. In a situation where multiple heat sources are coupled to a heat dissipating device, the increase in thermal resistance also increases due to thicker gap fillers used to compensate for non-alignment of surfaces. A solution is to provide an interface material or a substitute for the interface material to compensate for the increased thermal resistance associated with bonding of surfaces. Accordingly, a replacement of the interface material for bonding a single or multiple heat sources to a heat dissipating device that would reduce thermal resistance and the associated temperature increase across the bonded surface is desirable.

### SUMMARY OF THE INVENTION

It is therefore an object of the invention to provide a coupling for bonding a heat dissipating device to a heat source. It is a further object of the invention that the coupling reduce thermal resistance and increase thermal conductivity across the bonded surfaces.

A first aspect of the invention is a coupling for bonding a heat dissipating device to a heat source. The coupling includes a thermally conductive interface adapted to bond to a heat source and a diaphragm adapted to bond to a vapor chamber wall. The interface and the diaphragm are secured together. The diaphragm is preferably resilient, and is preferably hermetically sealed with a wall of the vapor chamber. The diaphragm is preferably comprised of a material selected from the group consisting of: a beryllium-copper composition, stainless steel, or a thermally conductive material having a resilient characteristic. The interface is preferably rigid, and is preferably comprised of a material selected from the group consisting of: aluminum, aluminum alloy, copper, copper alloy, or an alternative thermally conductive material.

A second aspect of the invention is a method for increasing thermal conductivity between a heat source and a heat exchanger. An interface is secured to a diaphragm, and the diaphragm is mounted to a vapor chamber wall. The interface preferably bonds to the heat source. The diaphragm preferably hermetically seals the vapor chamber wall. The diaphragm is preferably resilient, and is preferably comprised of a material selected from the group consisting of: a beryllium-copper composition, stainless steel, or a thermally conductive material or composition having a resilient characteristic. The interface is preferably rigid, and is preferably comprised of a material selected from the group consisting of: aluminum, aluminum alloy, copper, copper alloy, or an alternative thermally conductive material.

Other features and advantages of this invention will become apparent from the following detailed description of the presently preferred embodiment of the invention, taken in conjunction with the accompanying drawings.

### BRIEF DESCRIPTION OF THE DRAWINGS

FIG. 1 is a perspective view of a prior art heat sink coupled to a printed circuit board.

FIG. 2 is an elevational view of a heat sink coupled to a printed circuit board according to the invention.

FIG. 3 is a sectional view of the coupling of FIG. 2, and is suggested for printing on the first page of the issued patent.

FIG. 4 is a top view of the coupling of FIG. 3.

FIG. 5 is an elevational view of a heat sink coupled to two dies on a printed circuit board according to the invention.

FIG. 6 is a bottom view of the heat sink of FIG. 5.

FIG. 7 is a top view of a circuit board assembly showing the heat sink and coupling of FIGS. 5 and 6.

### DESCRIPTION OF THE PREFERRED EMBODIMENT

Overview

Heat sinks remove heat from power dissipating devices in and around electronic equipment. In general, a traditional heat sink has multiple thermally conductive fins affixed to a base of thermally conductive material. The base is mounted to a heat source such as a printed circuit board or an alternative power dissipating electronic device that produces heat. Thermal resistance in and around the base of the heat sink occurs due to imperfections in the surface of the base and the surface of the printed circuit board. These imperfections result in increased temperature in and around the heat sink. Accordingly, it is desirable to implement a novel coupling that mitigates thermal resistance associated with bonding of misaligned surfaces.

Technical Background

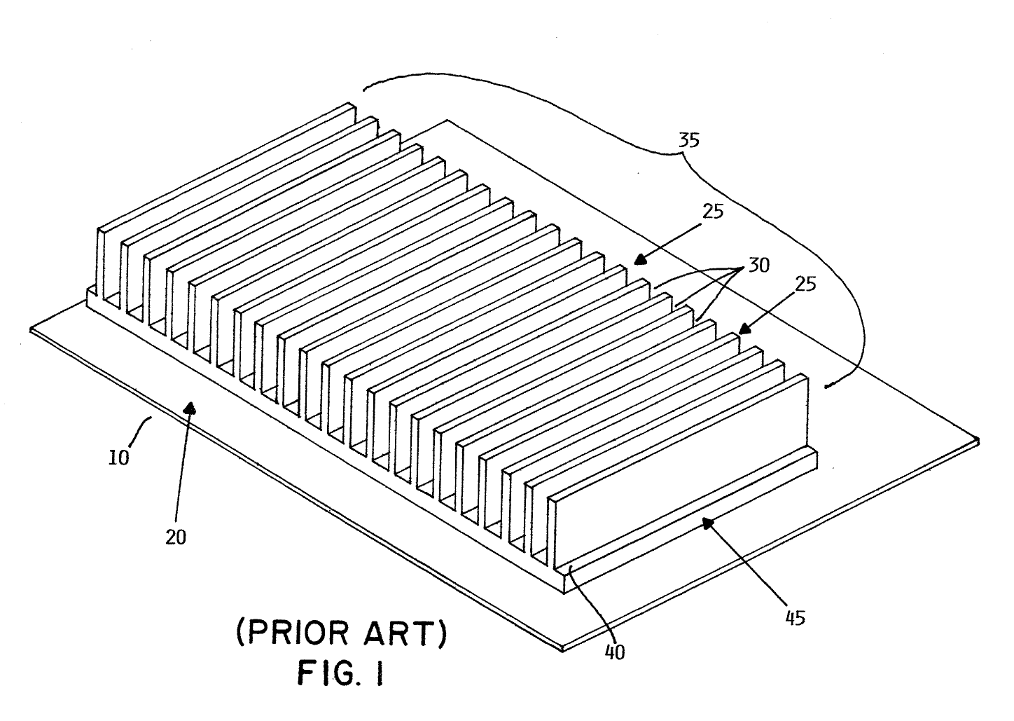

FIG. 1 is a perspective view of a prior art heat sink apparatus 10 coupled to a printed circuit board 20. The heat sink 10 has a plurality of aligned fins 25 separated by channels 30. The fins 25 in combination with the channels 30 form a fin field 35. The fin field 35 is affixed to a thermally conductive base 40, which is affixed to a vapor chamber 45. The vapor chamber 45 is a form of a heat pipe that is used to effectively transfer heat. Heat pipes are useful in improving the performance of heat sinks in electronic cooling applications. The vapor chamber 45 is a planar heat pipe that spreads heat in two dimensions. The base 40 of the heat sink 10 is the top surface of the vapor chamber 45. Accordingly, as shown in FIG. 1, the heat sink 10 is mounted to the vapor chamber 45, which is secured to the printed circuit board 20.

Flexible Thermal Coupling

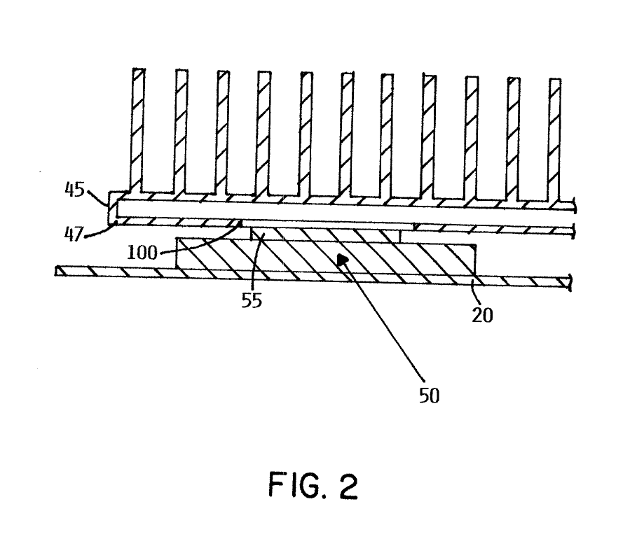

FIG. 2 is a sectional view of the prior art heat sink 10 apparatus of FIG. 1 with a coupling 100 mounted between the heat sink 10 and a die 55. The printed circuit board 20 has a chip carrier 50 mounted on the board 20, and a die 55 affixed to a top surface of the chip carrier 50. The vapor chamber 45 is coupled to a top surface of the die 55. In the prior art, an interface material, such as a gap filler, is placed on the top surface of the die 55 and/or the bottom surface of the vapor chamber in the area coupled to the die. The interface material is used to reduce thermal resistance associated with the coupling of the two surfaces.

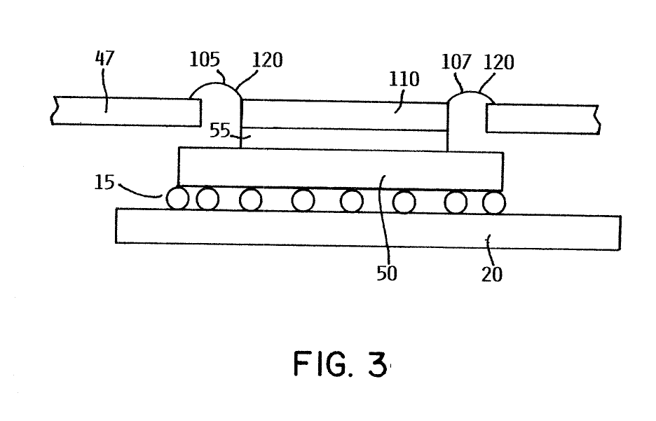

As shown in FIG. 2, a coupling 100 is mounted within the bottom wall 47 of the vapor chamber 45, and is adapted to bond the vapor chamber 45 to the die 55. The coupling is used in place of or in conjunction with an interface material, such as a gap filler, and functions to reduce thermal resistance. A more detailed view of the coupling 100 is shown in FIG. 3. Both the interface 110 and the diaphragm 120 are illustrated in greater detail. A printed circuit board 20 is shown with a ball grid array 15, a chip carrier 50, and a die 55. The interface 110 of the coupling 100 is bonded to the top surface of the die 55. As shown, the portion of the bottom wall 47 of the vapor chamber 45 has been removed to accommodate the coupling 100. The diaphragm 120 hermetically seals the vapor chamber as it extends from the vapor chamber at 105 and 107. Accordingly, the function of the vapor chamber is not compromised as the diaphragm hermetically seals the openings in the vapor chamber wall.

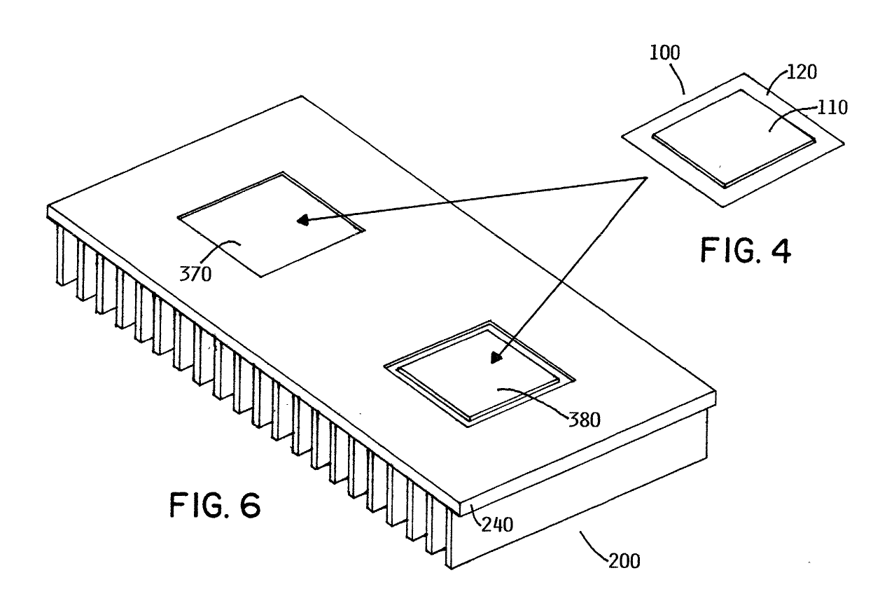

FIG. 4 is an illustration of a top view of the coupling 100. The diaphragm 120 may be concentric with the interface 110 and have a greater square area so that there is a spacing between the perimeter of the interface 110 and the perimeter of the diaphragm 120. The diaphragm 110 is resilient in nature to provide flexibility in mounting the interface to heat sources, such as dies and chips, that have surfaces that are either coplanar or misaligned with the surface of the interface. The diaphragm's material is a composition of Beryllium and Copper, or a thermally conductive composition having a resilient property. The composition provides the resilient characteristics necessary for bonding of co-planar or misaligned surfaces, and is also thermally conductive. This allows the coupling to function as a seal to the vapor chamber. The thickness of the diaphragm can vary depending upon the environment in which it is intended for use. The interface 110 of the coupling 100 is rigid and is preferably comprised of a thermally conductive material, such as Copper, a Copper alloy, Aluminum, an Aluminum alloy, or an alternative thermally conductive material to provide heat transfer from the heat source to the vapor chamber 240. Accordingly, the diaphragm 120 and the interface 110 are bonded together to function as a flexible coupling for bonding co-planar or misaligned surfaces.

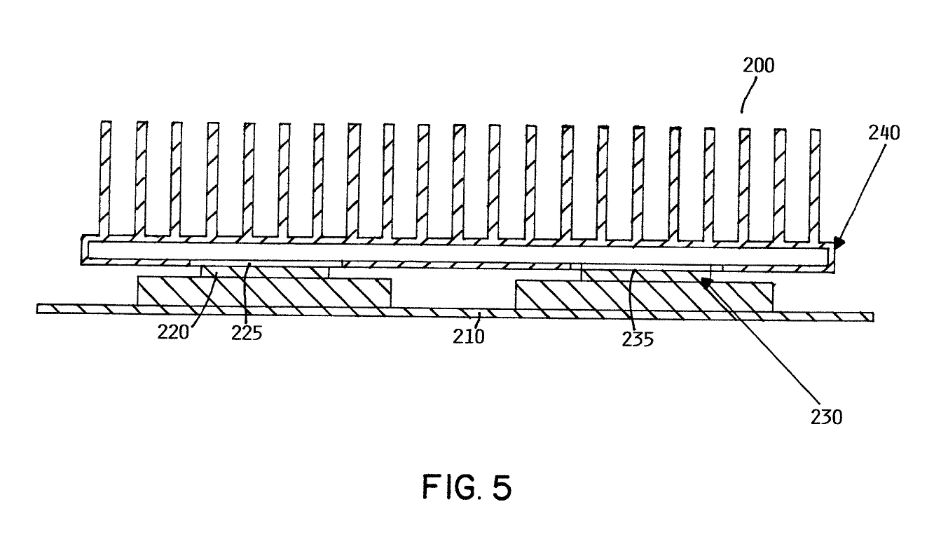

The use of the flexible coupling is not limited to joining a single heat sink to a single heat source, as shown in FIG. 2. The use of the flexible coupling independent of or in conjunction with an interface material allows for multiple bonding of co-planar surfaces as well as misaligned surfaces. FIG. 5 is an illustration of one heat sink apparatus 200 bonded to multiple dies 220 and 230. Each of the dies 220 and 230 are mounted on the printed circuit board 210. The heat sink 200 is mounted across both dies 220 and 230 of the printed circuit board 210. The heat sink 200 has two flexible couplings 225 and 235 secured to the vapor chamber 240. The coupling is integral to the vapor chamber. Each of the couplings 225 and 235 has a thermally conductive interface to bond with the dies 220 and 230 and a diaphragm to secure to and seal the vapor chamber 240. The couplings provide the ability to bond multiple dies to a single heat sink without increasing the quantity of a thermal interface material and effectively reducing thermal resistance associated with bonding of coplanar or misaligned surfaces. FIG. 6 is a bottom view of the base of the heat sink 200 of FIG. 5. The heat sink 200 is designed to bond to two dies of a printed circuit board to a single heat sink as shown by the two openings 370 and 380 in the base of the vapor chamber 240. Accordingly, the coupling 100 accommodates bonding multiple heat sources to a single heat exchanger.

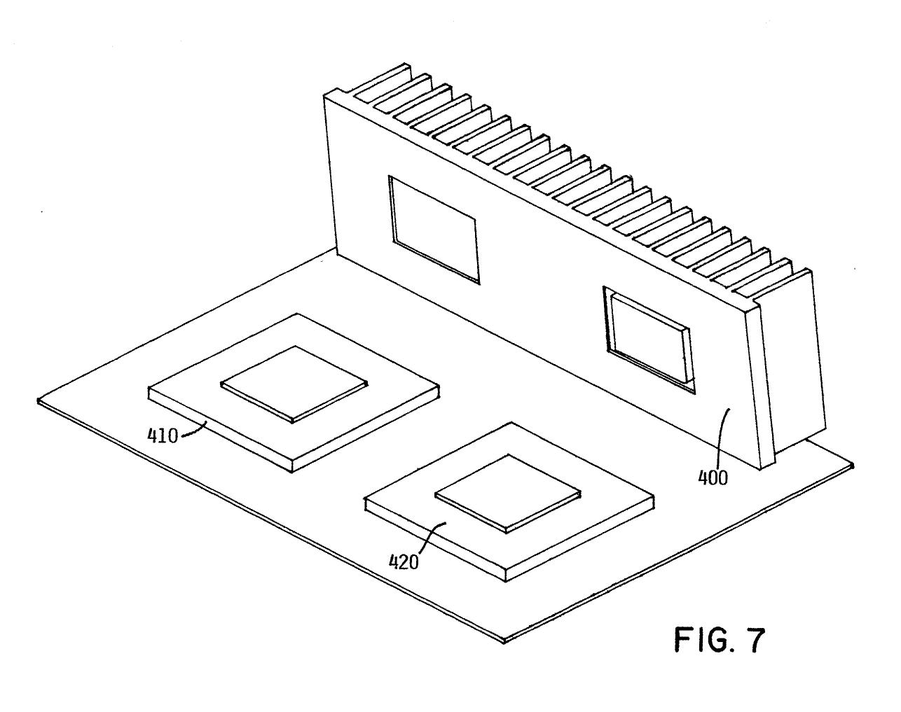

The coupling is provided to bond a surface of the vapor chamber to a heat source. The interface of the coupling may be directly bonded to the heat source, or indirectly with the use of an interface material. Although an interface material may not be a necessary component between the surfaces of the heat source and the interface, the interface material enhances the ability to separate the heat sink from the heat source. Separation of the two surfaces is accommodating when it is necessary or desirable to replace either or both the heat sink and/or the heat source. FIG. 7 is a top view of a heat sink 400 that bonds with two heat sources 410, 420. The heat sink 400 is shown in a raised position to demonstrate how the heat sink may be removed from the heat source(s). This allows for repair and/or replacement of either or both the heat sources or the printed circuit board on which they are mounted. Use of an interface material between the interface and the heat source removes the requirement to epoxy or otherwise permanently affix the interface to the heat source. Accordingly, applying an interface material to the interface surface of the coupling mitigates thermal resistance and allows for easier removal of the heat exchanger from the heat source(s).

Advantages Over the Prior Art

Prior art heat dissipation apparatus utilize an interface material to bond to a heat source. The interface material is utilized to reduce thermal resistance associated with bonding of non-coplanar surfaces. However, use of an interface material or an increased quantity of interface material also increases thermal resistance. The flexible diaphragm of the preferred embodiment overcomes the issues of thermal resistance associated with bonding of coplanar and/or misaligned surfaces by allowing a uniform bond-line surface. The flexible diaphragm could be a substitute for the requirement of a non-uniform bond-line thermal interface material. In addition, the use of the flexible diaphragm accommodates mounting a single heat dissipating device to multiple heat sources, wherein the heat sources may or may not be coplanar.

### Alternative Embodiments

It will be appreciated that, although specific embodiments of the invention have been described herein for purposes of illustration, various modifications may be made without departing from the spirit and scope of the invention. In particular, the coupling may be comprised of an alternative composition. The diaphragm must be resilient and thermally conductive, and a material having these characteristics may be substituted for the beryllium copper preferred composition. In addition, while the coupling of the preferred embodiment is shown to cover a portion of the face of the heat sink, the coupling may also cover the entire base of the heat sink. The dimensions of the coupling may vary depending upon the dimensions of the base of the heat sink. Accordingly, the scope of protection of this invention is limited only by the following claims and their equivalents.

We claim:

1. A heat sink coupling comprising:
(a) a thermally conductive interface adapted to bond to a heat source; and
(b) a diaphragm adapted to bond to a vapor chamber.

2. The coupling of claim 1, wherein said diaphragm provide a uniform bondline.

3. The coupling of claim 1, wherein said diaphragm is resilient.

4. The coupling of claim 1, wherein said diaphragm is hermetically sealed with a wall of said vapor chamber.

5. The coupling of claim 1, wherein said diaphragm is comprised of a material selected from the group consisting of: a Beryllium-Copper composition, stainless steel, or a thermally conductive material or composition having a resilient characteristic.

6. The coupling of claim 1, wherein said interface is fixed to said diaphragm.

7. The coupling of claim 1, wherein said interface is rigid.

8. The coupling of claim 1, wherein said interface is comprised of a material selected from the group consisting of: Aluminum, Aluminum alloy, Copper, Copper alloy, or a thermally conductive material.

9. The coupling of claim 1, wherein said interface and said heat source comprise misaligned surfaces.

10. A method for increasing thermal conductivity between a heat source and a heat exchanger comprising:
(d) securing an interface to a diaphragm; and
(e) mounting said diaphragm to a vapor chamber wall.

11. The method of claim 10, further comprising bonding said interface to said heat source.

12. The method of claim 10, further hermetically sealing said diaphragm with said vapor chamber wall.

13. The method of claim 10, wherein said diaphragm provides a uniform bondline surface.

14. The method of claim 10, wherein said diaphragm is resilient.

15. The method of claim 10, wherein said interface is rigid.

16. The method of claim 10, further comprising mounting a plurality of heat sources to said heat exchanger.

17. The method of claim 10, wherein said coupling is comprised of a material selected from the group consisting of: a Beryllium-Copper composition, stainless steel, or a thermally conductive material or composition having a resilient characteristic.

18. The method of claim 10, wherein said interface is comprised of a material selected from the group consisting of: Aluminum, Aluminum alloy, Copper, Copper alloy, or a thermally conductive material.

19. A heat sink coupling comprising:
an interface adapted to bond to a heat source; and
a resilient diaphragm adapted to bond to a vapor chamber;
wherein said interface and said diaphragm are thermally conductive.

20. The coupling of claim 19, wherein said interface and said heat source comprise surfaces selected from the group consisting of: planar and misaligned.
